(19) United States
(12) Patent Application Publication
(10) Pub. No.: US 2026/0282537 A1
(43) Pub. Date: Sep. 17, 2026

(54) SEMICONDUCTOR DEVICE AND METHOD FOR MANUFACTURING SEMICONDUCTOR DEVICE

(71) Applicant: INSTITUTE OF MICROELECTRONICS, CHINESE ACADEMY OF SCIENCES, Beijing (CN)

(72) Inventors: Yongliang LI, Beijing (CN); Xin WANG, Beijing (CN); Haoyan LIU, Beijing (CN); Xiaolei WANG, Beijing (CN)

(21) Appl. No.: 19/277,668

(22) Filed: Jul. 23, 2025

(30) Foreign Application Priority Data
Mar. 13, 2025 (CN) 202510300562.6

(51) Int. Cl. H10D 84/85; H10D 30/00; H10D 30/01; H10D 62/10; H10D 84/01

(52) U.S. Cl. CPC H10D 84/856; H10D 30/0191; H10D 30/502; H10D 62/102; H10D 62/121; H10D 84/0167; H10D 84/0186; H10D 84/0188; H10D 84/851

(57) ABSTRACT

A semiconductor device and a method are provided. The semiconductor device includes a substrate, first and second transistors, and a first isolation structure. The first isolation structure is between source/drain regions of the second transistor and source/drain regions and/or channel region of the first transistor. An active structure of the second transistor has a length less than that of an active structure of the first transistor, and/or the active structure of the second transistor has a width less than that of the active structure of the first transistor. At least one pair of adjacent source/drain contact structures belonging to the first and second transistors and located on the same side in the length direction of the gate stack structures are spaced apart, and the source/drain contact structures of the first and second transistors are in a vertical space of a region where the first and second transistors are located.

### CROSS REFERENCE TO RELATED APPLICATION

This application claims priority to Chinese Patent Application No. 202510300562.6, filed on Mar. 13, 2025, the entire content of which is incorporated herein in its entirety by reference.

### TECHNICAL FIELD

The present disclosure relates to a field of semiconductor technology, and in particular to a semiconductor device and a method for manufacturing a semiconductor device.

### BACKGROUND

A three-dimensional stacked complementary transistor includes vertically stacked N-type and P-type transistors, which eliminates a lateral spacing between the N-type and P-type transistors and allows for a further increase in an effective channel width, thereby improving the operating performance and integration density of a semiconductor device.

However, in related three-dimensional stacked complementary transistors, source/drain contact structures require additional routing space, which is not conducive to the miniaturization of semiconductor device.

### SUMMARY

An objective of the present disclosure is to provide a semiconductor device and a method for manufacturing a semiconductor device. By configuring a length and/or a width of an active structure of a second transistor to be respectively less than a length and/or a width of an active structure of a first transistor, source/drain contact structures of the first transistor and the second transistor are both located in a vertical space of a region where the first transistor and the second transistor are located, without the need for additional layout area, thereby facilitating miniaturization of the semiconductor device and improving an integration density of the semiconductor device.

To achieve the above objective, in a first aspect, the present disclosure provides a semiconductor device. The semiconductor device includes: a semiconductor base substrate, a first transistor, a second transistor, and a first isolation structure, where the first transistor and the second transistor are spaced apart on the semiconductor base substrate in a thickness direction of the semiconductor base substrate, the second transistor is located above the first transistor, and the first isolation structure is disposed between source/drain regions of the second transistor and source/drain regions of the first transistor and/or between the source/drain regions of the second transistor and a channel region of the first transistor; where, in a length direction of gate stack structures of the first transistor and the second transistor, an active structure of the second transistor has a length less than that of an active structure of the first transistor, and/or in a width direction of channel regions of the first transistor and the second transistor, the active structure of the second transistor has a width less than that of the active structure of the first transistor; the active structure includes the channel region and the source/drain regions located on both sides of the channel region in the length direction; and where at least one pair of adjacent two source/drain contact structures respectively belonging to the first transistor and the second transistor and located on the same side in the length direction of the gate stack structures are spaced apart from each other, and the source/drain contact structure of the first transistor and the source/drain contact structure of the second transistor are both located in a vertical space of a region where the first transistor and the second transistor are located.

When the above-mentioned technical solution is adopted, the first transistor and the second transistor of the semiconductor device are spaced apart in the thickness direction of the semiconductor base substrate, and the first isolation structure is disposed between the source/drain regions of the second transistor and the source/drain regions and/or channel region of the first transistor to prevent leakage. It is apparent that the first transistor and the second transistor may constitute a three-dimensional stacked complementary transistor (CFET device) to enhance the integration density of the semiconductor device.

Furthermore, when the length of the active structure of the second transistor is less than that of the first transistor in the length direction of the gate stack structures of the first transistor and the second transistor, the difference in length between the active structure of the first transistor and the active structure of the second transistor allows for at least one pair of adjacent two source/drain contact structures, which respectively belong to the first transistor and the second transistor and are located on the same side in the length direction of the gate stack structures, to be spaced apart at least in the length direction of the gate stack structures. In other words, both the source/drain contact structure of the first transistor and the source/drain contact structure of the second transistor may be located in the vertical space of the region where the first transistor and the second transistor are located, without the need to adopt L-like structures to physically insulate the two spaced-apart source/drain contact structures, which facilitates the miniaturization of the semiconductor device. Similarly, when the width of the active structure of the second transistor is less than that of the first transistor in the width direction of the channel regions of the first transistor and the second transistor, the difference in width between the active structure of the first transistor and the active structure of the second transistor allows for the two source/drain contact structures to be spaced apart at least in the width direction of the channel region. This also helps to ensure that the layout and routing of all the source/drain contact structures of the first transistor and the second transistor do not occupy additional layout area at device periphery while physically insulating these two source/drain contact structures, thereby enhancing the integration density of the semiconductor device.

In an example, in the first transistor and the second transistor, the two source/drain contact structures spaced apart on the same side in the length direction of the gate stack structures extend along a direction perpendicular to a surface of the semiconductor base substrate.

In an example, the semiconductor device further includes an insulating dielectric layer, where the insulating dielectric layer covers the second transistor and a portion of the first transistor exposed outside the second transistor; where the source/drain contact structures corresponding to the first transistor and the second transistor include a first connecting portion; the first connecting portion is located above one of the source/drain regions of the first transistor, and is electrically connected to one of the source/drain regions of the first transistor and one of the source/drain regions of the second transistor located on the same side in the length direction of the gate stack structures; and the first connecting portion penetrates through a portion of the insulating dielectric layer covering one of the source/drain regions of the first transistor and located at the same height as the second transistor.

In an example, the first connecting portion extends along a direction perpendicular to a surface of the semiconductor base substrate.

In an example, the semiconductor device further includes an insulating dielectric layer, where the insulating dielectric layer covers the second transistor and a portion of the first transistor exposed outside the second transistor; where the source/drain contact structures corresponding to the first transistor and the second transistor include a second connecting portion and a third connecting portion; the second connecting portion and the third connecting portion are disposed on the same side of the first transistor and the second transistor in the length direction of the gate stack structures and are spaced apart from each other; where the second connecting portion penetrates through a portion of the insulating dielectric layer covering the other one of the source/drain regions of the first transistor and located at the same height as the second transistor, and is electrically connected to the other one of the source/drain regions of the first transistor; and where the third connecting portion penetrates through a portion of the insulating dielectric layer covering the other one of the source/drain regions of the second transistor, and is electrically connected to the other one of the source/drain regions of the second transistor.

In an example, when the length of the active structure of the second transistor is less than that of the active structure of the first transistor, the channel region of the second transistor has a length less than that of the channel region of the first transistor; and/or the source/drain region of the second transistor has a length less than or equal to that of the source/drain region of the first transistor.

In an example, a center line of the channel region of the second transistor in the length direction of the gate stack structure coincides with a center line of the channel region of the first transistor in the length direction of the gate stack structure.

In an example, a sidewall of the channel region of the second transistor in the width direction is aligned with a sidewall of the channel region of the first transistor in the width direction; or a center line of the channel region of the second transistor in the width direction coincides with a center line of the channel region of the first transistor in the width direction.

In an example, the second transistor is a comb-shaped field-effect transistor.

In an example, the first transistor is a gate-all-around transistor; the channel region of the second transistor has a plurality of nanostructure layers spaced apart in the thickness direction of the semiconductor base substrate and a connecting portion disposed on a side of the plurality of nanostructure layers in the width direction; and the number of nanostructure layers in the channel region of the second transistor is less than that in the channel region of the first transistor.

In an example, at least one of the first transistor and the second transistor is a gate-all-around transistor.

In an example, the semiconductor device further includes a second isolation structure disposed between the gate stack structure of the first transistor and the gate stack structure of the second transistor.

In a second aspect, the present disclosure further provides a method for manufacturing a semiconductor device, including: forming a fin-like structure on a semiconductor base substrate, where the fin-like structure includes a first fin portion, a semiconductor isolation layer, and a second fin portion arranged in sequence along a thickness direction of the semiconductor base substrate; selectively etching the second fin portion so that a remaining portion of the second fin portion has a length less than that of the first fin portion and/or has a width less than that of the first fin portion; forming a first transistor based on the first fin portion using a semiconductor manufacturing process; removing the semiconductor isolation layer, and forming a first isolation structure at least on source/drain regions of the first transistor; forming a second transistor based on the second fin portion using a semiconductor manufacturing process; and forming source/drain contact structures in electrical contact with the source/drain regions of the first transistor and source/drain regions of the second transistor, where at least one pair of adjacent two source/drain contact structures respectively belonging to the first transistor and the second transistor and located on the same side in a length direction of gate stack structures are spaced apart, and the source/drain contact structure of the first transistor and the source/drain contact structure of the second transistor are both located in a vertical space of a region where the first transistor and the second transistor are located.

In an example, the forming a first transistor, forming a first isolation structure and forming a second transistor include: forming a mask structure across the fin-like structure, and etching away a portion of the fin-like structure exposed outside the mask structure; epitaxially forming the source/drain regions of the first transistor on both sides of a remaining portion of the first fin portion; forming the first isolation structure at least on the source/drain regions of the first transistor; epitaxially forming the source/drain regions of the second transistor on both sides of the remaining portion of the second fin portion; removing the mask structure, and forming channel regions respectively from the remaining portion of the first fin portion and the remaining portion of the second fin portion; and forming gate stack structures around peripheries of the channel regions.

In an example, after forming the fin-like structure on the semiconductor base substrate and before forming the mask structure across the fin-like structure, the second fin portion is selectively etched so that the width of the remaining portion of the second fin portion is less than the width of the first fin portion.

In an example, after etching away the portion of the fin-like structure exposed outside the mask structure and before epitaxially forming the source/drain regions of the second transistor on both sides of the remaining portion of the second fin portion, the second fin portion is selectively etched so that the length of the remaining portion of the second fin portion is less than the length of the first fin portion.

In an example, the second fin portion includes at least one semiconductor stack layer, and each semiconductor stack layer includes a sacrificial layer and a channel layer disposed on the sacrificial layer; and the method for manufacturing a semiconductor device further includes: after forming the fin-like structure on the semiconductor base substrate and before selectively etching the second fin portion, performing selective epitaxial growth on a side of the second fin portion in the width direction to form a connecting portion, so that each channel layer of the second fin portion is electrically connected through the connecting portion.

In an example, the method for manufacturing a semiconductor device further includes: after forming the mask structure across the fin-like structure and before etching away the portion of the fin-like structure exposed outside the mask structure, removing a remaining portion of the semiconductor isolation layer; and forming a second isolation structure between the remaining portion of first fin portion and the remaining portion of the second fin portion.

The beneficial effects of the second aspect and its various implementations in the present disclosure may be understood with reference to the analysis of the beneficial effects in the first aspect and its various implementations, which will not be repeated here.

### BRIEF DESCRIPTION OF THE DRAWINGS

The accompanying drawings described here are intended to provide a further understanding of the present disclosure and constitute a part of the present disclosure. The exemplary embodiments of the present disclosure and their descriptions are used to explain the present disclosure and do not constitute an improper limitation of the present disclosure. In the accompanying drawings:

FIG. 1 shows a first schematic structural diagram of a semiconductor device during a manufacturing process provided by an embodiment of the present disclosure;

FIG. 2 shows a second schematic structural diagram of a semiconductor device during a manufacturing process provided by an embodiment of the present disclosure;

FIG. 3 shows a third schematic structural diagram of a semiconductor device during a manufacturing process provided by an embodiment of the present disclosure;

FIG. 4 shows a fourth schematic structural diagram of a semiconductor device during a manufacturing process provided by an embodiment of the present disclosure;

FIG. 5 shows a fifth schematic structural diagram of a semiconductor device during a manufacturing process provided by an embodiment of the present disclosure;

FIG. 6 shows a sixth schematic structural diagram of a semiconductor device during a manufacturing process provided by an embodiment of the present disclosure;

FIG. 7 shows a seventh schematic structural diagram of a semiconductor device during a manufacturing process provided by an embodiment of the present disclosure;

FIG. 8 shows an eighth schematic structural diagram of a semiconductor device during a manufacturing process provided by an embodiment of the present disclosure;

FIG. 9 shows a ninth schematic structural diagram of a semiconductor device during a manufacturing process provided by an embodiment of the present disclosure;

FIG. 10 shows a tenth schematic structural diagram of a semiconductor device during a manufacturing process provided by an embodiment of the present disclosure;

FIG. 11 shows an eleventh schematic structural diagram of a semiconductor device during a manufacturing process provided by an embodiment of the present disclosure;

FIG. 12 shows a twelfth schematic structural diagram of a semiconductor device during a manufacturing process provided by an embodiment of the present disclosure;

FIG. 13 shows a thirteenth schematic structural diagram of a semiconductor device during a manufacturing process provided by an embodiment of the present disclosure;

FIG. 14 shows a fourteenth schematic structural diagram of a semiconductor device during a manufacturing process provided by an embodiment of the present disclosure;

FIG. 15 shows a fifteenth schematic structural diagram of a semiconductor device during a manufacturing process provided by an embodiment of the present disclosure;

FIG. 16 shows a sixteenth schematic structural diagram of a semiconductor device during a manufacturing process provided by an embodiment of the present disclosure;

FIG. 17 shows a seventeenth schematic structural diagram of a semiconductor device during a manufacturing process provided by an embodiment of the present disclosure;

FIG. 18 shows an eighteenth schematic structural diagram of a semiconductor device during a manufacturing process provided by an embodiment of the present disclosure;

FIG. 19 shows a nineteenth schematic structural diagram of a semiconductor device during a manufacturing process provided by an embodiment of the present disclosure;

FIG. 20 shows a twentieth schematic structural diagram of a semiconductor device during a manufacturing process provided by an embodiment of the present disclosure;

FIG. 21 shows a twenty-first schematic structural diagram of a semiconductor device during a manufacturing process provided by an embodiment of the present disclosure;

FIG. 22 shows a twenty-second schematic structural diagram of a semiconductor device during a manufacturing process provided by an embodiment of the present disclosure;

FIG. 23 shows a twenty-third schematic structural diagram of a semiconductor device during a manufacturing process provided by an embodiment of the present disclosure;

FIG. 24 shows a twenty-fourth schematic structural diagram of a semiconductor device during a manufacturing process provided by an embodiment of the present disclosure;

FIG. 25 shows a twenty-fifth schematic structural diagram of a semiconductor device during a manufacturing process provided by an embodiment of the present disclosure;

FIG. 26 shows a twenty-sixth schematic structural diagram of a semiconductor device during a manufacturing process provided by an embodiment of the present disclosure;

FIG. 27 shows a twenty-seventh schematic structural diagram of a semiconductor device during a manufacturing process provided by an embodiment of the present disclosure;

FIG. 28 shows a twenty-eighth schematic structural diagram of a semiconductor device during a manufacturing process provided by an embodiment of the present disclosure;

FIG. 29 shows a twenty-ninth schematic structural diagram of a semiconductor device during a manufacturing process provided by an embodiment of the present disclosure;

FIG. 30 shows a thirtieth schematic structural diagram of a semiconductor device during a manufacturing process provided by an embodiment of the present disclosure;

FIG. 31 shows a thirty-first schematic structural diagram of a semiconductor device during a manufacturing process provided by an embodiment of the present disclosure;

FIG. 32 shows a thirty-second schematic structural diagram of a semiconductor device during a manufacturing process provided by an embodiment of the present disclosure; and

FIG. 33 shows a thirty-third schematic structural diagram of a semiconductor device during a manufacturing process provided by an embodiment of the present disclosure.

Reference numerals: 11: semiconductor base substrate, 12: first transistor, 13: second transistor, 14: first isolation structure, 15: source/drain region, 16: channel region, 17: gate stack structure, 18: source/drain contact structure, 19: second isolation structure, 20: shallow trench isolation structure, 21: insulating dielectric layer, 22: fin-like structure, 23: first fin portion, 24: semiconductor isolation layer, 25: second fin portion, 26: mask structure, 27: gate spacer, 28: sacrificial gate, 29: sacrificial layer, 30: channel layer, 31: connecting portion, 32: first connecting portion, 33: second connecting portion, 34: third connecting portion.

### DETAILED DESCRIPTION OF EMBODIMENT

The following description of embodiments of the present disclosure will be made with reference to the accompanying drawings. However, it should be understood that these descriptions are merely illustrative and are not intended to limit the scope of the present disclosure. Furthermore, in the following description, well-known structures and techniques are omitted to avoid unnecessarily obscuring the concept of the present disclosure.

The drawings illustrate various schematic structural diagrams according to embodiments of the present disclosure. These drawings are not drawn to scale. Some details have been enlarged for clarity, and some details may be omitted. The shapes of regions and layers shown in the drawings, as well as their relative sizes and positional relationships, are merely illustrative and may vary in practice due to manufacturing tolerances or technical limitations. Those skilled in the art may design regions/layers of different shapes, sizes, or relative positions as needed.

In the context of the present disclosure, when a layer/element is described as being “on” another layer/element, it may be directly on the other layer/element, or there may be an intermediate layer/element between them. In addition, if a layer/element is described as being “on” another layer/element in an orientation, it may be “under” the other layer/element when the orientation is reversed. In order to make the technical problems to be solved, the technical solutions to be provided and the beneficial effects to be achieved by the present disclosure more apparent, detailed descriptions of the present disclosure are provided below with reference to the drawings and embodiments. It should be understood that the specific embodiments described herein are merely intended to illustrate the present disclosure and are not intended to limit the present disclosure.

In addition, the terms “first”, “second” and the like are merely used for descriptive purposes and should not be construed to indicate or imply relative importance, or to imply any specific number of the technical features described. Thus, features defined with “first” and “second” may explicitly or implicitly refer to one or more such features. In the description of the present disclosure, the term “a plurality of” means two or more, unless otherwise specifically defined. The term “at least one” means one or more, unless otherwise specifically defined.

In the description of the present disclosure, it should be noted that unless otherwise clearly specified and limited, terms such as “mounted”, “connected” and “coupled” should be interpreted in a broad sense. For example, a connection may refer to a fixed connection, a detachable connection or an integral connection; it may also refer to a mechanical connection or an electrical connection; it may also refer to a direct connection or an indirect connection via an intermediate medium; and it may also refer to an internal communication or interaction between two elements. Those of ordinary skill in the art may understand the specific meanings of these terms in the present disclosure according to the specific circumstances.

A three-dimensional stacked complementary transistor includes vertically stacked N-type and P-type transistors, which eliminates a lateral spacing between the N-type and P-type transistors and allows for a further increase in an effective channel width, thereby improving the operating performance and integration density of the semiconductor device.

However, in related three-dimensional stacked complementary transistors, upper and lower transistors typically have channel regions and source/drain regions with identical lengths and widths. To separately lead out at least one pair of adjacent source/drain contact structures of the upper and lower transistors, it is needed to adopt L-like structures for the source/drain contact structures to prevent physical insulation between the two adjacent source/drain contact structures located on the same side. This design requires additional layout area, which is not conducive to the miniaturization of semiconductor devices. Although an introduction of Buried Power Rail (BPR) structure may reduce layout and routing area, the buried power rail technology requires additional bonding or similar steps, which increases manufacturing costs of semiconductor devices and hinders mass production of semiconductor devices.

To solve the above technical problems, embodiments of the present disclosure provide a semiconductor device and a method for manufacturing the same. In the semiconductor device provided by embodiments of the present disclosure, a first transistor and a second transistor are spaced apart on a semiconductor base substrate in a thickness direction of the semiconductor base substrate. Furthermore, an active structure of the second transistor has a length and/or width less than that of an active structure of the first transistor, so that the source/drain contact structures of the first transistor and the second transistor are both located in a vertical space of a region where the first transistor and the second transistor are located, without the need to occupy additional layout area, which facilitates the miniaturization of the semiconductor device and improves the integration density of the semiconductor device.

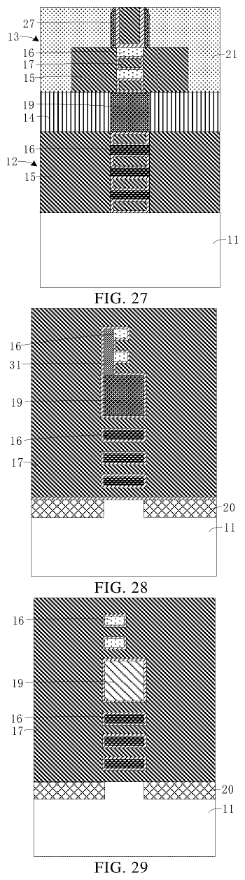

In a first aspect, an embodiment of the present disclosure provides a semiconductor device. As shown in FIG. 27 to FIG. 33, the semiconductor device includes a semiconductor base substrate 11, a first transistor 12, a second transistor 13, and a first isolation structure 14. The first transistor 12 and the second transistor 13 are spaced apart on the semiconductor base substrate 11 in the thickness direction of the semiconductor base substrate 11, and the second transistor 13 is located above the first transistor 12. The first isolation structure 14 is disposed between source/drain regions 15 of the second transistor 13 and source/drain regions 15 and/or channel region 16 of the first transistor 12. In a length direction of gate stack structures 17 of the first transistor 12 and the second transistor 13, an active structure of the second transistor 13 has a length less than that of an active structure of the first transistor 12, and/or in a width direction of the channel regions 16 of the first transistor 12 and the second transistor 13, the active structure of the second transistor 13 has a width less than that of the active structure of the first transistor 12. The active structure includes a channel region 16 and source/drain regions 15 located on both sides of the channel region 16 in the length direction. At least one pair of adjacent two source/drain contact structures 18 respectively belonging to the first transistor 12 and the second transistor 13 and located on the same side in the length direction of the gate stack structures 17 are spaced apart, and the source/drain contact structures 18 of the first transistor 12 and the second transistor 13 are both located in the vertical space of the region where the first transistor 12 and the second transistor 13 are located.

When the above technical solution is adopted, as shown in FIG. 27 to FIG. 33, the first transistor 12 and the second transistor 13 of the semiconductor device are spaced apart in the thickness direction of the semiconductor base substrate 11, and the first isolation structure 14 is disposed between the source/drain regions 15 of the second transistor 13 and the source/drain regions 15 and/or channel region 16 of the first transistor 12 to prevent leakage. It is apparent that the first transistor 12 and the second transistor 13 may constitute a three-dimensional stacked complementary transistor (CFET device) to increase the integration density of the semiconductor device. Furthermore, as shown in FIG. 27 to FIG. 33, when the length of the active structure of the second transistor 13 is less than that of the first transistor 12 in the length direction of the gate stack structures 17 of the first transistor 12 and the second transistor 13, the difference in length between the active structure of the first transistor 12 and the active structure of the second transistor 13 allows for at least one pair of adjacent two source/drain contact structures 18, which respectively belong to the first transistor 12 and the second transistor 13 and are located on the same side in the length direction of the gate stack structures 17, to be spaced apart at least in the length direction of the gate stack structures 17. In other words, both the source/drain contact structure of the first transistor 12 and the source/drain contact structure of the second transistor 13 may be located in the vertical space of the region where the first transistor 12 and the second transistor 13 are located, without adopting L-like structures to physically insulate the two spaced-apart source/drain contact structures 18, which facilitates the miniaturization of the semiconductor device. Similarly, when the width of the active structure of the second transistor 13 is less than that of the first transistor 12 in the width direction of the channel region 16 of the first transistor 12 and the channel region 16 of the second transistor 13, the difference in width between the active structure of the first transistor 12 and the active structure of the second transistor 13 allows for the two source/drain contact structures to be spaced apart at least in the width direction of the channel region 16. This also helps to ensure that the layout and routing of all the source/drain contact structures 18 of the first transistor 12 and the second transistor 13 do not occupy additional layout area at device periphery while physically insulating these two source/drain contact structures 18, thereby enhancing the integration density of the semiconductor device.

In practical applications, the semiconductor base substrate may be a semiconductor substrate on which no structures have yet been formed, such as a silicon substrate, a silicon-germanium substrate, a germanium substrate, or a silicon-on-insulator substrate.

Exemplarily, the semiconductor base substrate may also be a semiconductor substrate on which some structures have already been formed. For example, when the semiconductor device provided by embodiments of the present disclosure is applied to a second layer or a higher layer in an integrated circuit, the semiconductor base substrate may include a semiconductor substrate, an underlying device formed on the semiconductor substrate, and an interlayer dielectric layer for isolating the underlying devices, etc.

In some cases, as shown in FIG. 27 to FIG. 33, the semiconductor device provided by embodiments of the present disclosure may further include an insulating dielectric layer 21. The insulating dielectric layer 21 covers the second transistor 13 and a portion of the first transistor 12 exposed outside the second transistor 13. A top surface of the insulating dielectric layer 21 is flush with a top surface of the gate stack structure 17 of the second transistor 13, so as to protect the source/drain regions 15 from being affected by the etching and cleaning operations for removing structures such as the sacrificial gate 28, thereby improving a yield of the semiconductor device.

The insulating dielectric layer may be made of any insulating material such as silicon oxide, silicon nitride, or silicon oxynitride, which is not specifically limited here.

As for the first transistor and the second transistor, embodiments of the present disclosure do not impose any specific limitations on device types of the first transistor and the second transistor, as long as they may be formed on the semiconductor base substrate.

Exemplarily, the first transistor and/or the second transistor may be a fin field-effect transistor or a gate-all-around transistor.

Optionally, as shown in FIG. 27 to FIG. 32, both the first transistor 12 and the second transistor 13 may be gate-all-around transistors in order to improve their gate control capabilities and enhance the drive performance of the semiconductor device.

Optionally, as shown in FIG. 28, the second transistor 13 may be a comb-shaped field-effect transistor. In this case, the second transistor 13 further includes a connecting portion 31 used to electrically connect different layers of nanostructures that are spaced apart in the thickness direction of the semiconductor base substrate 11, which helps increase a conduction area of the channel region 16 of the second transistor 13 and improve the electrical performance of the second transistor 13. Based on this, the first transistor 12 may be a gate-all-around transistor; the channel region 16 of the second transistor 13 may have a plurality of nanostructure layers spaced apart in the thickness direction of the semiconductor base substrate 11 and a connecting portion 31 disposed on a side of the plurality of nanostructure layers in the width direction. Moreover, the number of nanostructure layers in the channel region 16 of the second transistor 13 may be less than that in the channel region 16 of the first transistor 12, so as to increase a vertical integration density of the semiconductor device and facilitate the miniaturization of the semiconductor device.

Certainly, when the second transistor is a comb-shaped field-effect transistor, the channel region of the second transistor may have a height equal to or greater than that of the channel region of the first transistor. The respective heights of the channel regions of the first transistor and the second transistor may be determined according to the requirements for electrical characteristics of the two transistors in practical application scenarios, which are not specifically limited here.

In terms of structure, the specific structures of the first transistor and the second transistor may be determined according to their device types and actual requirements, which are not specifically limited here.

Exemplarily, when the first transistor and/or the second transistor is a fin field-effect transistor, the fin field-effect transistor may include a channel region, source/drain regions, a gate stack structure, and a source/drain contact structure. The source/drain regions are disposed on both sides of the channel region in the length direction, and the gate stack structure is disposed on the top and sidewalls of the channel region. The source/drain contact structure is disposed above the source/drain regions and electrically connected to the source/drain regions.

Exemplarily, when the first transistor and/or the second transistor is a gate-all-around transistor, the gate-all-around transistor may include a channel region, source/drain regions, a gate stack structure, and a source/drain contact structure. The source/drain regions are disposed on both sides of the channel region in the length direction, and the gate stack structure surrounds an outer periphery of the channel region. The source/drain contact structure is disposed above the source/drain regions and electrically connected to the source/drain regions. Specifically, the channel region may include only a single nanostructure layer; or, as shown in FIG. 27 to FIG. 32, the channel region 16 may also include a plurality of nanostructure layers spaced apart in the thickness direction of the semiconductor base substrate 11. The number of nanostructure layers in the channel region 16 of the first transistor 12 and that in the channel region 16 of the second transistor 13 are not specifically limited in embodiments of the present disclosure. Specifically, different nanostructure layers in the channel region 16 may be made of the same or different materials.

It should be noted that the source region of the second transistor and the source region of the first transistor may be located on the same side in the length direction of the gate stack structures; or the drain region of the second transistor and the source region of the first transistor may be located on the same side in the length direction of the gate stack structures.

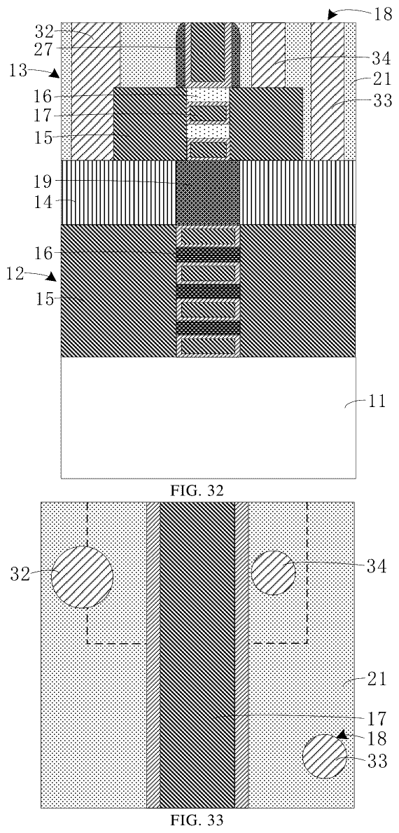

Furthermore, as shown in FIG. 31, each pair of adjacent two source/drain contact structures 18 located on the same side in the length direction of the gate stack structures 17 in the first transistor 12 and the second transistor 13 are spaced apart. Alternatively, as shown in FIG. 32, one pair of adjacent two source/drain contact structures 18 located on the same side in the length direction of the gate stack structures 17 in the first transistor 12 and the second transistor 13 are spaced apart from each other, while the other pair of adjacent two source/drain contact structures 18 located on the same side in the length direction of the gate stack structures 17 are electrically connected to each other.

Exemplarily, as shown in FIG. 32 and FIG. 33, the source/drain contact structures 18 corresponding to the first transistor 12 and the second transistor 13 may include a first connecting portion 32. The first connecting portion 32 is located above one of the source/drain regions 15 of the first transistor 12, and is electrically connected to one of the source/drain regions 15 of the first transistor 12 and one of the source/drain regions 15 of the second transistor 13 located on the same side in the length direction of the gate stack structures 17. The first connecting portion 32 penetrates through a portion of the insulating dielectric layer 21 covering one of the source/drain regions 15 of the first transistor 12 and located at the same height as the second transistor 13. In practical applications, the drain region in the source/drain regions 15 of the first transistor 12 and the drain region in the source/drain regions 15 of the second transistor 13 may be located on the same side in the length direction of the gate stack structures 17, and the first connecting portion 32 may be electrically connected to both the drain region of the first transistor 12 and the drain region of the second transistor 13 to output a voltage. Certainly, which one of the source/drain regions of the first transistor 12 and which one of the source/drain regions of the second transistor 13 are electrically connected to the first connecting portion 32 may be determined according to actual requirements, which is not specifically limited here.

Exemplarily, as shown in FIG. 32 and FIG. 33, the source/drain contact structures 18 corresponding to the first transistor 12 and the second transistor 13 may further include a second connecting portion 33 and a third connecting portion 34. The second connecting portion 33 and the third connecting portion 34 are disposed on the same side of the first transistor 12 and the second transistor 13 in the length direction of the gate stack structures 17 and are spaced apart from each other. The second connecting portion 33 penetrates through a portion of the insulating dielectric layer 21 covering the other one of the source/drain regions 15 of the first transistor 12 and located at the same height as the second transistor 13, and is electrically connected to the other one of the source/drain regions 15 of the first transistor 12. The third connecting portion 34 penetrates through a portion of the insulating dielectric layer 21 covering the other one of the source/drain regions 15 of the second transistor 13, and is electrically connected to the other one of the source/drain regions 15 of the second transistor 13. In practical applications, the source region in the source/drain regions 15 of the first transistor 12 may be electrically connected to the second connecting portion 33, and the source region in the source/drain regions 15 of the second transistor 13 may be electrically connected to the third connecting portion 34. One of the second connecting portion 33 and the third connecting portion 34 is connected to ground, and the other is connected to a power supply. Specifically, which one of the second connecting portion 33 and the third connecting portion 34 is connected to ground and which one is connected to the power supply may be determined according to the conductivity types of the first transistor 12 and the second transistor 13, which is not specifically limited here. Certainly, which one of the source/drain regions 15 of the first transistor 12 is electrically connected to the second connecting portion 33 and which one of the source/drain regions 15 of the second transistor 13 is electrically connected to the third connecting portion 34 may be determined according to actual requirements, which is not specifically limited here.

The specific morphology of the two source/drain contact structures located on the same side in the length direction of the gate stack structures in the first transistor and the second transistor may be determined according to their positional relationship. If the two are electrically connected, the structure may be of a wraparound type or similar. Certainly, as shown in FIG. 32 and FIG. 33, the first connecting portion 32 may also extend along the direction perpendicular to the surface of the semiconductor base substrate.

As shown in FIG. 31 and FIG. 32, if the two source/drain contact structures 18 located on the same side in the length direction of the gate stack structures are spaced apart from each other, they may both extend along the direction perpendicular to the surface of the semiconductor base substrate. In this case, the source/drain contact structures 18 may be simplified, and it is possible to obtain the source/drain contact structures 18 by simply etching to form contact holes and filling the contact holes with conductive materials, without the need to pre-embed conductive materials for leading out the source/drain regions 15. This may simplify the manufacturing process of the semiconductor device and help reduce the manufacturing cost.

In terms of materials, the source/drain regions and channel regions of the first transistor and the second transistor may be made of any semiconductor material such as silicon, silicon-germanium, or germanium, which is not specifically limited here. The source/drain region and the channel region may be made of the same or different materials. Moreover, the channel region of the first transistor and the channel region of the second transistor may be made of the same or different materials. The source/drain regions of the first transistor and the source/drain regions of the second transistor may be made of the same or different materials.

The gate stack structure of the first transistor and the gate stack structure of the second transistor each may include a gate dielectric layer disposed around a periphery the channel region, and a gate electrode located on the gate dielectric layer. The gate dielectric layer of the first transistor and/or the second transistor may be made of an insulating material such as HfO₂, ZrO₂, TiO₂, or Al₂O₃. The gate electrode of the first transistor and/or the second transistor may be made of a conductive material such as TiN, TaN, or TiSiN. The gate stack structure of the first transistor and the gate stack structure of the second transistor may be made of the same or different materials.

In some cases, as shown in FIG. 31 and FIG. 32, the semiconductor device provided by embodiments of the present disclosure may further include gate spacers 27. The gate spacers 27 are disposed on both sides of the gate stack structures 17 of the first transistor 12 and the second transistor 13 in the length direction, and used to isolate the gate stack structures 17 from adjacent other conductive structures, thereby reducing the risk of leakage. The gate spacers 27 may be made of any insulating material such as silicon oxide, silicon nitride, or silicon oxynitride.

In terms of device dimensions, the length of the active structure of the second transistor may be smaller than the length of the active structure of the first transistor only in the length direction of the gate stack structures of the first transistor and the second transistor.

Alternatively, the width of the active structure of the second transistor may be smaller than the width of the active structure of the first transistor only in the width direction of the channel regions of the first transistor and the second transistor.

Still alternatively, as shown in FIG. 27 to FIG. 33, the active structure of the second transistor 13 may be smaller than the active structure of the first transistor 12 in both the length and the width. In this case, at least one pair of adjacent source/drain contact structures 18 located on the same side in the length direction of the gate stack structures 17 in the first transistor 12 and the second transistor 13 may be spaced apart in both directions to further reduce the risk of leakage between the two.

Specifically, when the length of the active structure of the second transistor is less than that of the first transistor, it may be that only the channel region of the second transistor has a length less than that of the channel region of the first transistor; or only the source/drain regions of the second transistor have a length less than that of the source/drain regions of the first transistor; or it may be that the length of the channel region of the second transistor is less than that of the first transistor, and the length of the source/drain regions of the second transistor is less than or equal to that of the first transistor.

As for the difference in length between the active structure of the first transistor and the active structure of the second transistor, it may be set according to manufacturing accuracy and actual requirements, which is not limited here.

Furthermore, when the length of the active structure of the second transistor is less than that of the active structure of the first transistor, as shown in FIG. 31 and FIG. 32, a center line of the channel region 16 of the second transistor 13 in the length direction of the gate stack structure 17 may coincide with a center line of the channel region 16 of the first transistor 12 in the length direction of the gate stack structure 17. In this case, a second fin portion 25 used to form the second transistor 13 may be selectively etched in a direction from the source/drain region 15 to the channel region 16 to narrow the second fin portion 25, so that the length of the active structure of the second transistor 13 is less than that of the active structure of the first transistor 12. In this way, there is no need to additionally manufacture a mask to cover a side of the second fin portion 25, thereby simplifying the manufacturing process of the semiconductor device.

Alternatively, a sidewall of the channel region of the second transistor in the length direction of the gate stack structure may be aligned with a sidewall of the channel region of the first transistor in the length direction of the gate stack structure. In this case, if only a single pair of adjacent two source/drain contact structures located on the same side in the length direction of the gate stack structures in the first transistor and the second transistor are spaced apart, and the other pair of adjacent two source/drain contact structures located on the same side in the length direction of the gate stack structure are electrically connected, then the two electrically connected source/drain contact structures may be disposed on the side where the sidewalls of the channel regions of the first transistor and the second transistor in the length direction are aligned, and the two spaced-apart source/drain contact structures may be disposed on the side where the sidewalls of the channel regions of the first transistor and the second transistor in the length direction are staggered. This further reduces the risk of leakage between the two and decreases the manufacturing difficulty of the two spaced-apart source/drain contact structures.

When the width of the active structure of the second transistor is less than that of the first transistor, as shown in FIG. 28, FIG. 29 and FIG. 33, a sidewall of the channel region 16 of the second transistor 13 in the width direction may be aligned with a sidewall of the channel region 16 of the first transistor 12 in the width direction. In this case, the manufacturing difficulty of the mask structure which is used for the selective etching of the second fin portion 25 used to form the second transistor 13 is not high, which helps reduce the manufacturing difficulty of the semiconductor device. Moreover, the at least one pair of adjacent two source/drain contact structures 18 located on the same side in the length direction of the gate stack structure 17 in the first transistor 12 and the second transistor 13 may be spaced by a larger distance in the width direction of the channel region 16, which helps reduce the risk of leakage between the two and lower the manufacturing difficulty of the two spaced-apart source/drain contact structures 18.

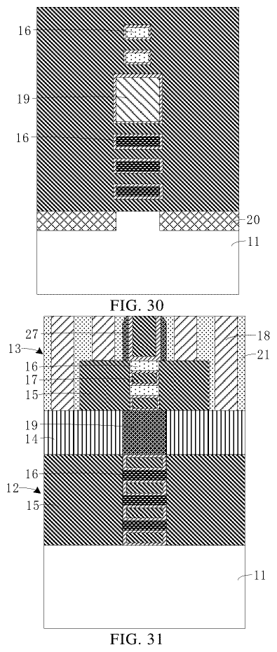

Alternatively, as shown in FIG. 30, the center line of the channel region 16 of the second transistor 13 in the width direction may coincide with the center line of the channel region 16 of the first transistor 12 in the width direction.

In an example, as shown in FIG. 31 and FIG. 32, the semiconductor device may further include a second isolation structure 19. The second isolation structure 19 is disposed between the gate stack structure 17 of the first transistor 12 and the gate stack structure 17 of the second transistor 13 to reduce electrical interference between the first transistor 12 and the second transistor 13 and improve the electrical performance of the semiconductor device. The second isolation structure 19 may be made of any insulating material such as silicon oxide or silicon nitride.

As for the first isolation structure, embodiments of the present disclosure do not impose specific limitations on the material and thickness of the first isolation structure, as long as the first isolation structure is capable of electrically isolating the source/drain regions of the second transistor from the source/drain regions and/or channel region of the first transistor.

Specifically, an arrangement position of the first isolation structure may be determined according to the lengths of the active structures of the first transistor and the second transistor, which is not specifically limited here. In particular, if the length of the active structure of the second transistor is less than that of the first transistor, the first isolation structure may be disposed at least between the source/drain regions of the second transistor and the channel region of the first transistor (and may also be disposed between the source/drain regions of the second transistor and the source/drain regions of the first transistor).

If the length of the active structure of the second transistor is equal to the length of the active structure of the first transistor, the first isolation structure may be disposed between the source/drain regions of the second transistor and the source/drain regions of the first transistor.

In some cases, as shown in FIG. 27 to FIG. 33, the semiconductor device provided by embodiments of the present disclosure may further include a shallow trench isolation structure 20. The shallow trench isolation structure 20 is formed on the semiconductor base substrate 11 to define an active region of the semiconductor base substrate 11, so as to reduce the risk of leakage and further improve the yield and operating performance of the semiconductor device.

The shallow trench isolation structure may be made of any insulating material such as silicon oxide, silicon nitride, or silicon oxynitride, which is not specifically limited here.

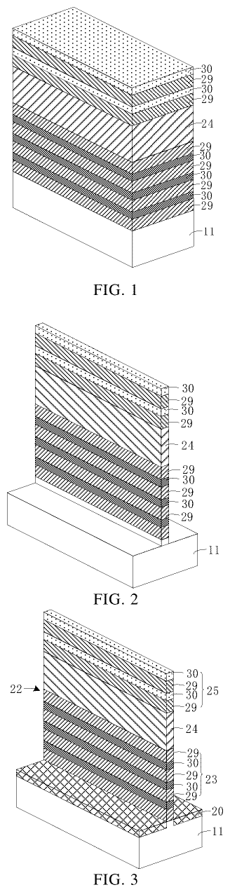

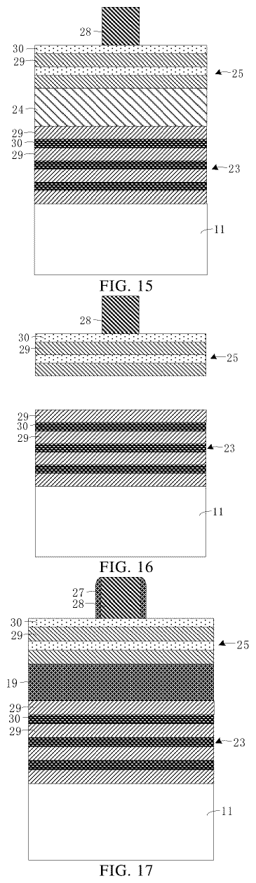

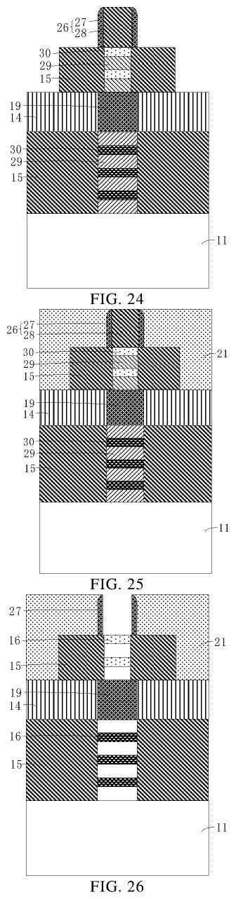

In a second aspect, an embodiment of the present disclosure provides a method for manufacturing a semiconductor device. The manufacturing process will be described below with reference to the cross-sectional views of operations shown in FIG. 1 to FIG. 33. Specifically, the method for manufacturing the semiconductor device includes the following steps. First, as shown in FIG. 1 to FIG. 3, a fin-like structure 22 is formed on a semiconductor base substrate 11. The fin-like structure 22 includes a first fin portion 23, a semiconductor isolation layer 24, and a second fin portion 25 arranged in sequence in a thickness direction of the semiconductor base substrate 11. Next, as shown in FIG. 4 to FIG. 23, the second fin portion 25 is selectively etched so that a remaining portion of the second fin portion 25 has a length less than that of the first fin portion 23, and/or the remaining portion of the second fin portion 25 has a width less than that of the first fin portion 23. Subsequently, as shown in FIG. 24 to FIG. 30, a first transistor 12 is formed based on the first fin portion 23 using a semiconductor manufacturing process. Next, as shown in FIG. 24 to FIG. 30, the semiconductor isolation layer 24 is removed; and a first isolation structure 14 is formed at least on the source/drain regions 15 of the first transistor 12. Then, as shown in FIG. 24 to FIG. 30, a second transistor 13 is formed based on the second fin portion 25 using a semiconductor manufacturing process. After that, as shown in FIG. 31 to FIG. 33, source/drain contact structures 18 are formed in electrical contact with the source/drain regions 15 of the first transistor 12 and the second transistor 13. At least one pair of adjacent two source/drain contact structures 18 respectively belonging to the first transistor 12 and the second transistor 13 and located on the same side in the length direction of the gate stack structures 17 are spaced apart, and the source/drain contact structure 18 of the first transistor 12 and the source/drain contact structure 18 of the second transistor 13 are both located in a vertical space of a region where the first transistor 12 and the second transistor 13 are located.

It should be noted that the semiconductor device formed by the manufacturing method provided in the second aspect of embodiments of the present disclosure has the same structure as the semiconductor device provided in the first aspect. Therefore, the beneficial effects of the second aspect and its various implementations in embodiments of the present disclosure may be understood with reference to the analysis of the beneficial effects in the first aspect and its various implementations, which will not be repeated here.

In practical manufacturing process, in the above-mentioned fin-like structure, the first fin portion is used to form the first transistor. Therefore, the specific structure of the first fin portion may be determined according to the device type and structure of the first transistor.

Exemplarily, when the first transistor is a fin field-effect transistor, the first fin portion may be a single-layer elongated semiconductor structure; or it may be an elongated semiconductor structure including multiple semiconductor layers. The material and width of the first fin portion may be respectively identical with those of the channel region of the first transistor.

Exemplarily, when the first transistor is a gate-all-around transistor, the first fin portion may include at least one semiconductor stack layer. Each semiconductor stack layer includes alternately stacked sacrificial layers and channel layers. In the alternately stacked sacrificial layers and channel layers, both the bottom film layer and the top film layer may be sacrificial layers. The channel layers of the first fin portion are used to form nanostructures in the channel region of the first transistor. Therefore, the width of the first fin portion and the material of the channel layers of the first fin portion may be determined according to the width and material of the channel region of the first transistor. As for the sacrificial layers of the first fin portion, the sacrificial layers of the first fin portion covered by the mask structure needs to be removed later to release the channel region of the first transistor. Moreover, when the sacrificial layers of the first fin portion are selectively removed, the second fin portion (or the channel layers of the second fin portion) remains intact. Accordingly, the sacrificial layers of the first fin portion may be made of any semiconductor material different from that of the channel layers of the first fin portion and from that of the second fin portion (or the channel layers of the second fin portion). For example, if the channel layers of the first fin portion and the channel layers of the second fin portion are both made of silicon, the sacrificial layers of the first fin portion may be made of silicon-germanium or germanium.

Similarly, since the second fin portion is used to form the second transistor, the specific structure of the second fin portion may be determined according to the device type and structure of the second transistor.

Exemplarily, when the second transistor is a fin field-effect transistor, the second fin portion may be a single-layer elongated semiconductor structure; or it may be an elongated semiconductor structure including multiple semiconductor layers. The material and width of the second fin portion may be identical with those of the channel region of the second transistor.

Exemplarily, when the second transistor is a gate-all-around transistor, the second fin portion may include at least one semiconductor stack layer. Each semiconductor stack layer includes a sacrificial layer and a channel layer located on the sacrificial layer. The channel layer of the second fin portion is used to form nanostructures in the channel region of the second transistor, so the material of the channel layer of the second fin portion may be determined according to the material of the channel region of the second transistor. As for the sacrificial layer of the second fin portion, the sacrificial layer of the second fin portion covered by the mask structure needs to be removed later to release the channel region of the second transistor. Moreover, when the sacrificial layer of the second fin portion is selectively removed, the first fin portion (or the channel layer of the first fin portion) remains intact. Therefore, the sacrificial layer of the second fin portion may be made of any semiconductor material different from that of the channel layer of the second fin portion and from that of the first fin portion (or the channel layer of the first fin portion). In addition, when both the first transistor and the second transistor are gate-all-around transistors, the sacrificial layer of the first fin portion and the sacrificial layer of the second fin portion may be made of the same material in order to reduce the constraints of epitaxial critical thickness, thereby improving a formation quality of the semiconductor device. Certainly, the two may also be made of different materials.

As for the semiconductor isolation layer of the fin-like structure, it serves as a placeholder. The semiconductor isolation layer not covered by the mask structure will be removed later. After the formation of the source/drain regions of the first transistor, a first isolation structure may be formed at least on the source/drain regions of the first transistor. Therefore, a thickness of the semiconductor isolation layer may be determined according to the thickness requirements of the first isolation structure. A material of the semiconductor isolation layer may be any semiconductor material different from that of the first fin portion and the second fin portion, which is not specifically limited here.

Exemplarily, as shown in FIG. 1, sacrificial layers 29 and channel layers 30 used to form the first fin portion and the second fin portion, as well as a semiconductor isolation layer 24, may be formed in the thickness direction of the semiconductor base substrate 11 using epitaxial growth or other processes. Then, as shown in FIG. 2, the sacrificial layers 29, the channel layers 30, the semiconductor isolation layer 24, and a portion of the semiconductor base substrate 11 are patterned to form Fin structures using photolithography, etching, and other processes. Next, as shown in FIG. 3, a shallow trench isolation structure 20 used to define active regions is formed between adjacent Fin structures using deposition, etching and other processes. A top height of the shallow trench isolation structure 20 is less than or equal to a bottom height of the bottommost sacrificial layer 29. A portion of the Fin-like structures exposed outside the shallow trench isolation structure 20 forms the fin-like structure 22.

It should be noted that if the semiconductor device being manufactured does not include the aforementioned shallow trench isolation structure, then only the sacrificial layer, the channel layer and the semiconductor isolation layer need to be patterned. The fin-like structure may be obtained directly after the patterning process.

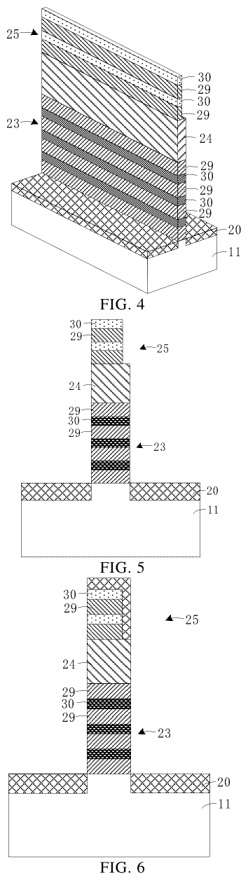

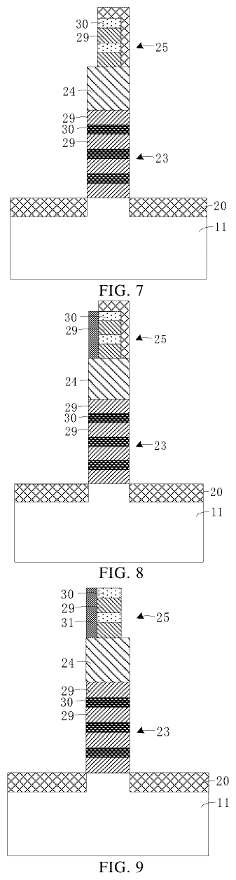

Exemplarily, if the second transistor being manufactured is a comb-shaped field-effect transistor, then after the formation of the fin-like structure, as shown in FIG. 4 and FIG. 5, the second fin portion 25 may be selectively etched using dry etching, wet etching or other processes to reduce the width of the second fin portion 25. Subsequently, as shown in FIG. 6, a mask is formed on an etched side of the second fin portion 25 using deposition or other processes. Then, as shown in FIG. 7 and FIG. 8, under the protection of the corresponding mask, the second fin portion 25 is further narrowed using an etching process. Next, by using epitaxial growth or other processes, a selective epitaxial growth is performed on a side of the second fin portion 25 in the width direction to form a connecting portion 31. Each channel layer 30 of the second fin portion 25 is electrically connected through the connecting portion 31. The connecting portion 31 may be made of any semiconductor material such as silicon, silicon-germanium, or germanium. As shown in FIG. 9, after the formation of the connecting portion 31, the corresponding mask may be removed using dry etching, wet etching, or other processes.

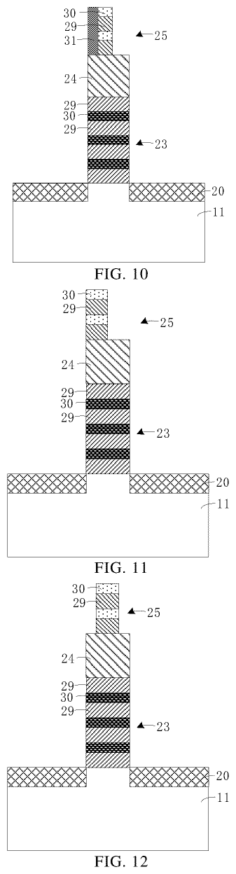

Exemplarily, if the width of the active structure of the second transistor is less than that of the first transistor in the semiconductor device being manufactured, then after the formation of the fin-like structure (or after the formation of the connecting portion), as shown in FIG. 10 to FIG. 12, the second fin portion 25 may be selectively etched using dry etching, wet etching or other processes under the protection of a corresponding mask, so that the remaining second fin portion 25 has a width less than that of the first fin portion 23. The mask may be any protective mask such as a photoresist mask. After the width of the second fin portion 25 is reduced, the mask may be removed using dry etching, wet etching, or other processes

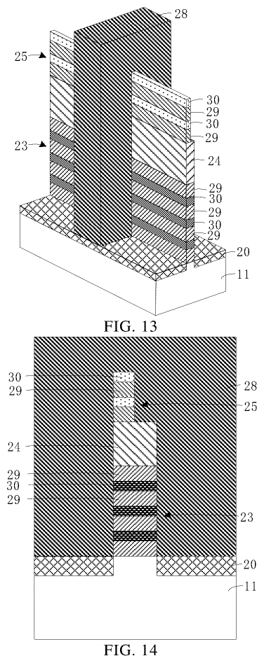

As shown in FIG. 13 to FIG. 15, a mask structure 26 across the fin-like structure 22 may be formed using deposition and etching processes. The specific structure and material of the mask structure 26 may be determined according to actual needs, as long as a protective function of the mask may be achieved in subsequent processes.

Exemplarily, as shown in FIG. 5, the mask structure 26 may include a sacrificial gate 28. The sacrificial gate 28 may be made of a material that is easy to remove, such as polysilicon.

Exemplarily, the mask structure may further include a gate oxide layer and a sacrificial gate located on the gate oxide layer. The gate oxide layer may be made of a material such as silicon oxide.

In an example, after forming the mask structure, the method for manufacturing the semiconductor device further includes the following steps. As shown in FIG. 16, the remaining semiconductor isolation layer is removed using dry etching, wet etching or other processes. Next, as shown in FIG. 17, a second isolation structure 19 is formed between the remaining first fin portion 23 and the remaining second fin portion 25 using deposition, etching and other processes.

It should be noted that gate spacers may be formed on both sides of the mask structure in the length direction while manufacturing the second isolation structure, so as to improve manufacturing efficiency of the semiconductor device. Alternatively, the second isolation structure may be manufactured after the formation of the gate spacers.

Next, as shown in FIG. 18, a portion of the fin-like structure exposed outside the mask structure 26 may be etched away using dry etching, wet etching or other processes (if the second isolation structure 19 has been already formed at this point, the second isolation structure 19 also needs to be selectively etched).

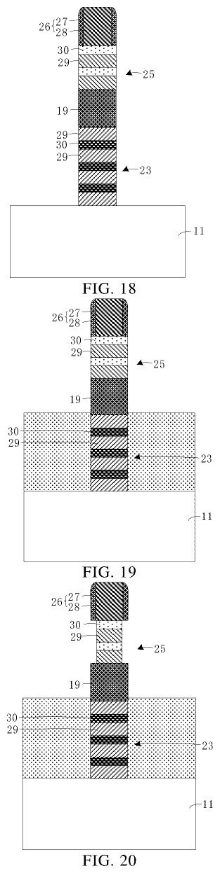

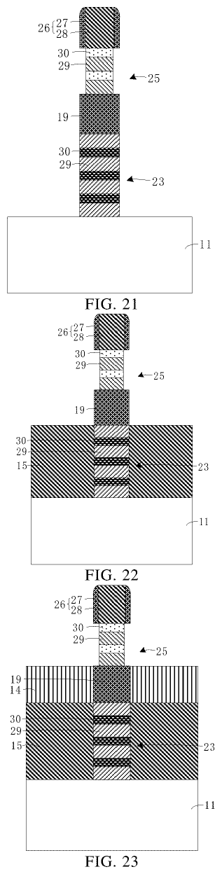

Exemplarily, if the length of the active structure of the second transistor is less than that of the first transistor in the semiconductor device being manufactured, then after the portion of the fin-like structure exposed outside the mask structure is etched away, as shown in FIG. 19, a mask may be formed using deposition, etching and other processes to at least cover the remaining first fin portion 23. Then, as shown in FIG. 20, under the protection of this mask, the second fin portion 25 is selectively etched using dry etching, wet etching or other processes so that the remaining second fin portion 25 has a length less than that of the first fin portion 23. After that, as shown in FIG. 21, the mask is removed.

Subsequently, as shown in FIG. 22, source/drain regions 15 of the first transistor 12 may be epitaxially formed on both sides of the remaining first fin portion using epitaxy growth or other processes.

Alternatively, in practical manufacturing process, it is possible to only selectively etch the second fin portion and the second isolation structure under the protection of the mask structure. Then, the exposed portion of the first fin portion may be doped using ion implantation or other processes to form the source/drain regions of the first transistor.

Next, as shown in FIG. 23, a first isolation structure 14 may be formed at least on the source/drain regions 15 of the first transistor 12 using deposition, etching and other processes.

Subsequently, as shown in FIG. 24, source/drain regions 15 of the second transistor 13 may be epitaxially formed on both sides of the remaining second fin portion using epitaxy growth or other processes.

Then, as shown in FIG. 25, an insulating dielectric layer 21 may be formed using deposition, planarization and other processes to cover the semiconductor base substrate 11. A top of the insulating dielectric layer 21 is flush with a top of the mask structure 26. As for the material of the insulating dielectric layer 21, reference may be made to the above description, which will not be repeated here.

Next, as shown in FIG. 26, the mask structure may be removed using dry etching, wet etching, or other processes.

After that, as shown in FIG. 26, the remaining first fin portion and the remaining second fin portion may be used to form respective channel regions 16.

The specific implementation of this operation may be determined according to the device types of the first transistor and the second transistor and actual needs. By way of example, if the first transistor and the second transistor are fin field-effect transistors, then after removal of the mask structure, the remaining first fin portion forms the channel region of the first transistor, and the remaining second fin portion forms the channel region of the second transistor.

Exemplarily, if the first transistor and/or the second transistor is a gate-all-around transistor, then after removal of the mask structure, it is needed to further remove the remaining sacrificial layer to release the channel region.

Then, as shown in FIG. 27 to FIG. 30, a gate stack structure 17 may be formed around a periphery of the channel region 16 using atomic layer deposition or other processes.

After that, as shown in FIG. 31 to FIG. 33, source/drain contact structures 18 are formed in electrical contact with the source/drain regions 15 of the first transistor 12 and the second transistor 13.

Specifically, it is possible to etch the insulating dielectric layer to form contact holes using photolithography, etching and other processes, and then form source/drain contact structures filled in the contact holes using physical vapor deposition or other processes.

In the above description, technical details such as patterning and etching for each layer are not provided. However, it should be understood by those skilled in the art that various technical means may be used to form layers, regions, etc. with desired shapes. Moreover, to form the same structure, those skilled in the art may design alternative methods that are not identical to those described above. Furthermore, although the various embodiments have been described separately above, this does not mean that the measures in different embodiments cannot be advantageously combined.

The embodiments of the present disclosure have been described above. However, these embodiments are provided solely for clearer explanation and are not intended to limit the scope of the present disclosure. The scope of the present disclosure is defined by the appended claims and their equivalents. Without departing from the scope of the present disclosure, various substitutions and modifications may be made by those skilled in the art, and such substitutions and modifications should fall within the scope of the present disclosure.

What is claimed is:

1. A semiconductor device, comprising: a semiconductor base substrate, a first transistor, a second transistor, and a first isolation structure;
wherein the first transistor and the second transistor are spaced apart on the semiconductor base substrate in a thickness direction of the semiconductor base substrate, the second transistor is located above the first transistor, and the first isolation structure is disposed between source/drain regions of the second transistor and source/drain regions of the first transistor and/or between the source/drain regions of the second transistor and a channel region of the first transistor;
wherein, in a length direction of gate stack structures of the first transistor and the second transistor, a length of an active structure of the second transistor is less than a length of an active structure of the first transistor, and/or in a width direction of channel regions of the first transistor and the second transistor, a width of the active structure of the second transistor is less than a width of the active structure of the first transistor; the active structure comprises the channel region and the source/drain regions located on both sides of the channel region in the length direction; and
wherein at least one pair of adjacent two source/drain contact structures respectively belonging to the first transistor and the second transistor and located on the same side in the length direction of the gate stack structures are spaced apart from each other, and the source/drain contact structure of the first transistor and the source/drain contact structure of the second transistor are both located in a vertical space of a region where the first transistor and the second transistor are located.

2. The semiconductor device according to claim 1, wherein in the first transistor and the second transistor, the two source/drain contact structures spaced apart on the same side in the length direction of the gate stack structures extend along a direction perpendicular to a surface of the semiconductor base substrate.

3. The semiconductor device according to claim 1, further comprising an insulating dielectric layer, wherein the insulating dielectric layer covers the second transistor and a portion of the first transistor exposed outside the second transistor;
wherein the source/drain contact structures corresponding to the first transistor and the second transistor comprise a first connecting portion; the first connecting portion is located above one of the source/drain regions of the first transistor, and is electrically connected to one of the source/drain regions of the first transistor and one of the source/drain regions of the second transistor located on the same side in the length direction of the gate stack structures; and the first connecting portion penetrates through a portion of the insulating dielectric layer covering one of the source/drain regions of the first transistor and located at the same height as the second transistor.

4. The semiconductor device according to claim 3, wherein the first connecting portion extends along a direction perpendicular to a surface of the semiconductor base substrate.

5. The semiconductor device according to claim 1, further comprising an insulating dielectric layer, wherein the insulating dielectric layer covers the second transistor and a portion of the first transistor exposed outside the second transistor;
wherein the source/drain contact structures corresponding to the first transistor and the second transistor comprise a second connecting portion and a third connecting portion; the second connecting portion and the third connecting portion are disposed on the same side of the first transistor and the second transistor in the length direction of the gate stack structures and are spaced apart from each other;
wherein the second connecting portion penetrates through a portion of the insulating dielectric layer covering the other one of the source/drain regions of the first transistor and located at the same height as the second transistor, and is electrically connected to the other one of the source/drain regions of the first transistor; and
wherein the third connecting portion penetrates through a portion of the insulating dielectric layer covering the other one of the source/drain regions of the second transistor, and is electrically connected to the other one of the source/drain regions of the second transistor.

6. The semiconductor device according to claim 1, wherein when the length of the active structure of the second transistor is less than the length of the active structure of the first transistor,
a length of the channel region of the second transistor is less than a length of the channel region of the first transistor; and/or a length of the source/drain region of the second transistor is less than or equal to a length of the source/drain region of the first transistor.

7. The semiconductor device according to claim 6, wherein a center line of the channel region of the second transistor in the length direction of the gate stack structure coincides with a center line of the channel region of the first transistor in the length direction of the gate stack structure.

8. The semiconductor device according to claim 1, wherein a sidewall of the channel region of the second transistor in the width direction is aligned with a sidewall of the channel region of the first transistor in the width direction; or
wherein a center line of the channel region of the second transistor in the width direction coincides with a center line of the channel region of the first transistor in the width direction.

9. The semiconductor device according to claim 1, wherein the second transistor is a comb-shaped field-effect transistor.

10. The semiconductor device according to claim 9, wherein the first transistor is a gate-all-around transistor; the channel region of the second transistor has a plurality of nanostructure layers spaced apart in the thickness direction of the semiconductor base substrate and a connecting portion disposed on a side of the plurality of nanostructure layers in the width direction; and
wherein the number of nanostructure layers in the channel region of the second transistor is less than the number of nanostructure layers in the channel region of the first transistor.

11. The semiconductor device according to claim 1, wherein at least one of the first transistor and the second transistor is a gate-all-around transistor; and/or
wherein the semiconductor device further comprises a second isolation structure disposed between the gate stack structure of the first transistor and the gate stack structure of the second transistor.

12. A method for manufacturing a semiconductor device, comprising:
forming a fin-like structure on a semiconductor base substrate, wherein the fin-like structure comprises a first fin portion, a semiconductor isolation layer, and a second fin portion arranged in sequence along a thickness direction of the semiconductor base substrate;
selectively etching the second fin portion so that a length of a remaining portion of the second fin portion is less than a length of the first fin portion and/or a width of the remaining portion of the second fin portion is less than a width of the first fin portion;
forming a first transistor based on the first fin portion using a semiconductor manufacturing process;
removing the semiconductor isolation layer, and forming a first isolation structure at least on source/drain regions of the first transistor;
forming a second transistor based on the second fin portion using a semiconductor manufacturing process; and
forming source/drain contact structures in electrical contact with the source/drain regions of the first transistor and source/drain regions of the second transistor, wherein at least one pair of adjacent two source/drain contact structures respectively belonging to the first transistor and the second transistor and located on the same side in a length direction of gate stack structures are spaced apart, and the source/drain contact structure of the first transistor and the source/drain contact structure of the second transistor are both located in a vertical space of a region where the first transistor and the second transistor are located.

13. The method for manufacturing a semiconductor device according to claim 12, wherein the forming a first transistor, forming a first isolation structure and forming a second transistor comprise:
forming a mask structure across the fin-like structure, and etching away a portion of the fin-like structure exposed outside the mask structure;
epitaxially forming the source/drain regions of the first transistor on both sides of a remaining portion of the first fin portion;
forming the first isolation structure at least on the source/drain regions of the first transistor;
epitaxially forming the source/drain regions of the second transistor on both sides of the remaining portion of the second fin portion;
removing the mask structure, and forming channel regions respectively from the remaining portion of the first fin portion and the remaining portion of the second fin portion; and
forming gate stack structures around peripheries of the channel regions.

14. The method for manufacturing a semiconductor device according to claim 13, wherein after forming the fin-like structure on the semiconductor base substrate and before forming the mask structure across the fin-like structure, the second fin portion is selectively etched so that the width of the remaining portion of the second fin portion is less than the width of the first fin portion.

15. The method for manufacturing a semiconductor device according to claim 13, wherein after etching away the portion of the fin-like structure exposed outside the mask structure and before epitaxially forming the source/drain regions of the second transistor on both sides of the remaining portion of the second fin portion, the second fin portion is selectively etched so that the length of the remaining portion of the second fin portion is less than the length of the first fin portion.

16. The method for manufacturing a semiconductor device according to claim 12, wherein the second fin portion comprises at least one semiconductor stack layer, and each semiconductor stack layer comprises a sacrificial layer and a channel layer disposed on the sacrificial layer; and
wherein the method for manufacturing a semiconductor device further comprises: after forming the fin-like structure on the semiconductor base substrate and before selectively etching the second fin portion, performing selective epitaxial growth on a side of the second fin portion in the width direction to form a connecting portion, so that each channel layer of the second fin portion is electrically connected through the connecting portion.

17. The method for manufacturing a semiconductor device according to claim 13, further comprising: after forming the mask structure across the fin-like structure and before etching away the portion of the fin-like structure exposed outside the mask structure,
removing a remaining portion of the semiconductor isolation layer; and
forming a second isolation structure between the remaining portion of first fin portion and the remaining portion of the second fin portion.
